(19) United States
(12) Patent Application Publication
(10) Pub. No.: US 2013/0137238 A1
(43) Pub. Date: May 30, 2013

(54) METHOD FOR FORMING HIGH MOBILITY CHANNELS IN III-V FAMILY CHANNEL DEVICES

(71) Applicants: Chun-Feng NIEH, Hsinchu City (TW); Huicheng CHANG, Tainan City (TW); Hung-Ta LIN, Hsinchu City (TW)

(72) Inventors: Chun-Feng NIEH, Hsinchu City (TW); Huicheng CHANG, Tainan City (TW); Hung-Ta LIN, Hsinchu City (TW)

(73) Assignee: TAIWAN SEMICONDUCTOR MANUFACTURING COMPANY, LTD., Hsinchu (TW)

(21) Appl. No.: 13/407,465

(22) Filed: Feb. 28, 2012

Related U.S. Application Data
(60) Provisional application No. 61/565,187, filed on Nov. 30, 2011.

(51) Int. Cl. H01L 21/762

(52) U.S. Cl. 438/424; 257/E21.546

(57) ABSTRACT

Provided is a method of fabricating a semiconductor device. The method includes forming a buffer layer over a surface of a silicon substrate. The method further includes forming openings that extend into the buffer layer. The method includes forming a shallow trench isolation (STI) structures in each of the openings. The method includes removing a predetermined amount of a top surface of the buffer layer relative to a top surface of the STI structures. The method includes forming an insulator layer over the top surface of the buffer layer and forming a channel layer over the insulator layer.

### CROSS-REFERENCE TO RELATED APPLICATION

The present application claims priority of U.S. Provisional Patent Application No. 61/565,187, filed on Nov. 30, 2011, which is incorporated herein by reference in its entirety.

### FIELD

The disclosure relates generally to the fabrication of semiconductor devices, and more particularly, to a method for forming high mobility channels in III-V family channel devices.

### BACKGROUND

The semiconductor integrated circuit (IC) industry has experienced rapid growth in recent years. Technological advances in IC materials and designs have produced generations of ICs where each generation has smaller and more complex circuits than the previous generation. These advances have increased the complexity of processing and manufacturing ICs and for these advances to be realized, similar developments in IC processing and manufacturing are needed. In the course of integrated circuit evolution, functional density (i.e., the number of interconnected devices per chip area) has generally increased while geometry size (i.e., the smallest component (or line) capable of being created using a fabrication process) has decreased.

The fabrication of some types of ICs involve forming a III-V family layer on a substrate. These types of IC devices include, as examples, light-emitting diode (LED) devices, radio frequency (RF) devices, and high power semiconductor devices. However, in the manufacture of certain semiconductor devices such as transistors using the III-V family layer, many process steps are often used to form high mobility channels. The high number of process steps lengthen the fabrication time and increases fabrication cost.

### BRIEF DESCRIPTION OF DRAWINGS

Aspects of the present disclosure are best understood from the following detailed description when read with the accompanying figures. It is emphasized that, in accordance with the standard practice in the industry, various features are not drawn to scale. In fact, the dimensions of the various features may be arbitrarily increased or reduced for clarity of discussion.

FIG. 1 is a flowchart of a method for fabricating a semiconductor device according to various aspects of the present disclosure.

FIGS. 2-8 are diagrammatic fragmentary cross-sectional side views of a portion of a wafer at various stages of fabrication in accordance with various aspects of the present disclosure.

### DETAILED DESCRIPTION

In the following description, numerous specific details are set forth to provide a thorough understanding of embodiments of the present disclosure. However, one having an ordinary skill in the art will recognize that embodiments of the disclosure can be practiced without these specific details. In some instances, well-known structures and processes are not described in detail to avoid unnecessarily obscuring embodiments of the present disclosure.

Reference throughout this specification to “one embodiment” or “an embodiment” means that a particular feature, structure, or characteristic described in connection with the embodiment is included in at least one embodiment of the present disclosure. Thus, the appearances of the phrases “in one embodiment” or “in an embodiment” in various places throughout this specification are not necessarily all referring to the same embodiment. Furthermore, the particular features, structures, or characteristics may be combined in any suitable manner in one or more embodiments. It should be appreciated that the following figures are not drawn to scale; rather, these figures are merely intended for illustration.

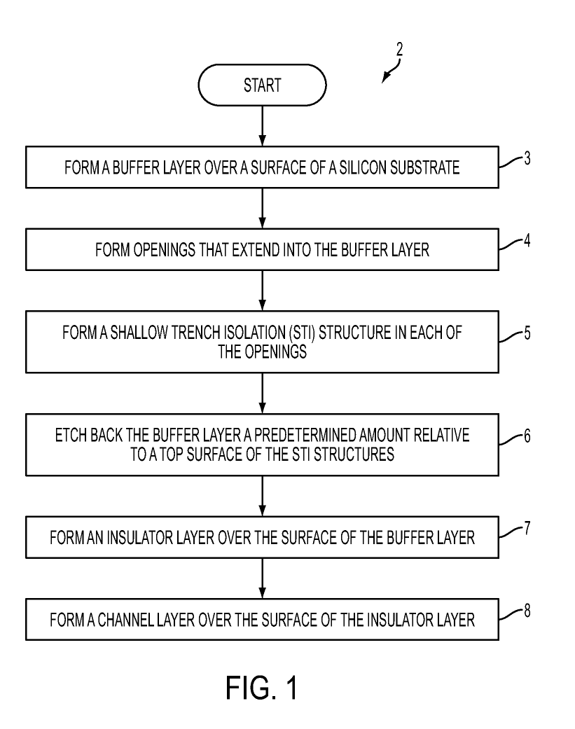

FIG. 1 is a flowchart of a method 2 for fabricating a semiconductor device according to various aspects of the present disclosure. Referring to FIG. 1, the method includes block 3, in which a buffer layer is formed over a surface of a silicon substrate. The method 2 includes block 4, in which a plurality of openings are formed in the buffer layer and extended therein. The method 2 includes block 5, in which a shallow trench isolation (STI) structure is formed in each of the openings. The method 2 includes block 6, in which a predetermined amount of a top surface of the buffer layer is removed relative to a top surface of the STI structures. The method 2 includes block 7, in which an insulator layer is formed over the top surface of the buffer layer. The method 2 includes block 8, in which a channel layer is formed over the insulator layer.

It is understood that additional processes may be performed before, during, or after the blocks 3-8 shown in FIG. 1 to complete the fabrication of the semiconductor device, but these additional processes are not discussed herein in detail for the sake of simplicity.

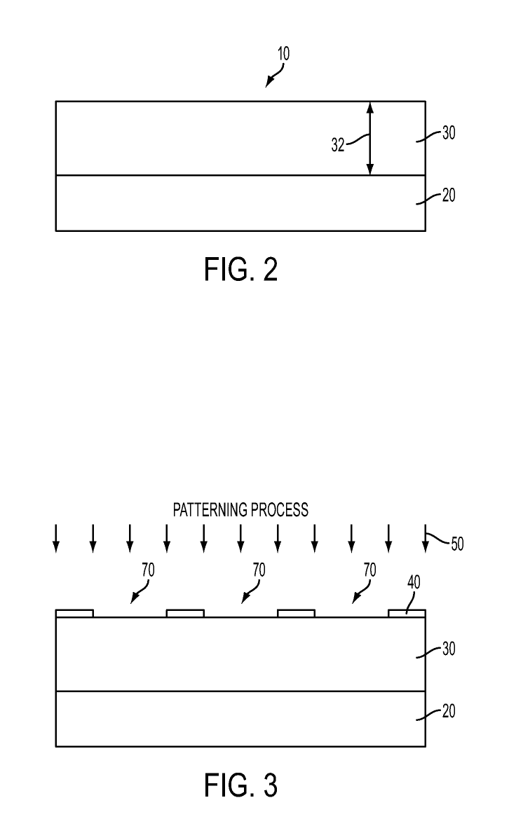

FIGS. 2-8 are diagrammatic fragmentary cross-sectional side views of a semiconductor device 10 at various fabrication stages according to embodiments of the method 2 of FIG. 1. It is understood that FIGS. 2-8 have been simplified for a better understanding of the inventive concepts of the present disclosure.

Referring to FIG. 2, a wafer 20 is provided. In the present embodiment, the wafer 20 includes a silicon material, and therefore may be referred to as a silicon wafer or silicon substrate hereafter. The wafer 20 includes other materials in some alternative embodiments, for example sapphire. It is also understood that the FIGS. 2-8 illustrate only a portion of the wafer 20 for the sake of simplicity, and that the wafer 20 may contain additional features that are not shown herein.

A buffer layer 30 is formed over the silicon wafer 20. Among other things, buffer layer 30 may reduce the stress (for example stress caused by lattice mismatch) between the silicon wafer 20 and a later to be formed III-V family layer. In an embodiment, the buffer layer 30 includes a IV family material and a III-V family material. The IV family material includes at least one element from the IV family of the periodic table, and the III-V family material includes at least one element from the III family of the periodic table and at least one element from the V family of the periodic table. According to one embodiment, the IV family material includes one of silicon germanium (SiGe) and germanium (Ge), and the III-V family material includes one of gallium aresenic (GaAs), indium gallium arsenic (InGaAs), and indium arsenic (InAs).

The buffer layer 30 may be formed by a metalorganic chemical vapor deposition (MOCVD) process. In other embodiments, the buffer layer 30 is formed by another suitable deposition process, such as for example chemical vapor deposition (CVD), low pressure chemical vapor deposition (LPCVD), atmospheric pressure chemical vapor deposition (APCVD), plasma enhanced chemical vapor deposition (PECVD), and reduced pressure chemical vapor deposition (RPCVD). The buffer layer 30 has a thickness 32 (measured vertically in FIG. 2). In some embodiments, the thickness 32 is in a range from about 1,000 Angstroms to about 10,000 Angstroms.

Referring to FIG. 3, a photoresist layer is deposited over the buffer layer 30. Thereafter, a patterning process 50 is performed to pattern the photoresist layer to form patterned photoresist layer 40. The patterned photoresist layer 40 contains a plurality of openings 70. The patterning process 50 may be carried out using a photolithography process known in the art, which may include one or more masking, exposing, developing, baking, and rinsing processes (not necessarily in this order).

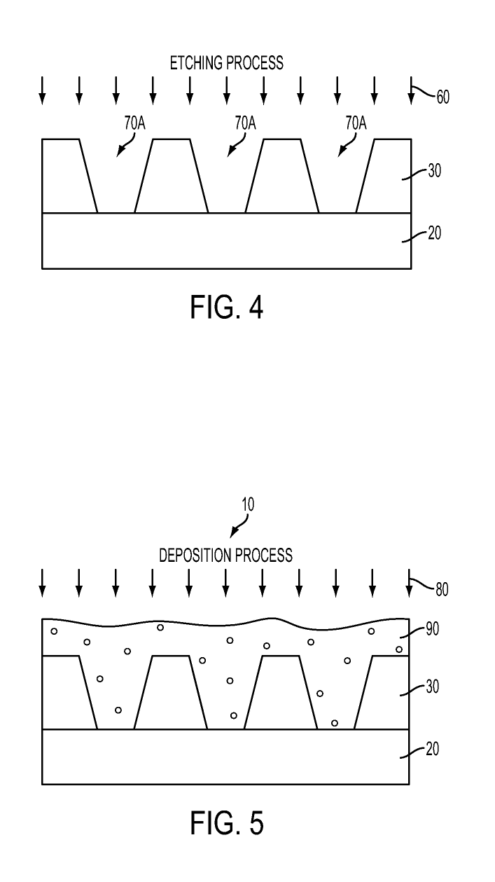

Referring now to FIG. 4, an etching process 60 is performed to extend the openings 70 into the buffer layer 30, thereby forming a plurality of recesses 70A. The recesses 70A may be referred to as trenches. The etching process 60 is performed using the patterned photoresist layer 40 as an etching mask. The etching process 60 may include a wet etching process or a dry etching process.

Referring now to FIG. 5, a deposition process 80 is performed to fill the recesses 70A with a dielectric material 90. In some embodiments, the deposition process 80 includes a high-density plasma (HDP) deposition process. In other embodiments, the deposition process 80 includes other deposition techniques known in the art, for example chemical vapor deposition (CVD), physical vapor deposition (PVD), atomic layer deposition (ALD), or another suitable technique. In some embodiments, the dielectric material 90 includes silicon oxide. The dielectric material 90 completely fills the recesses 70A.

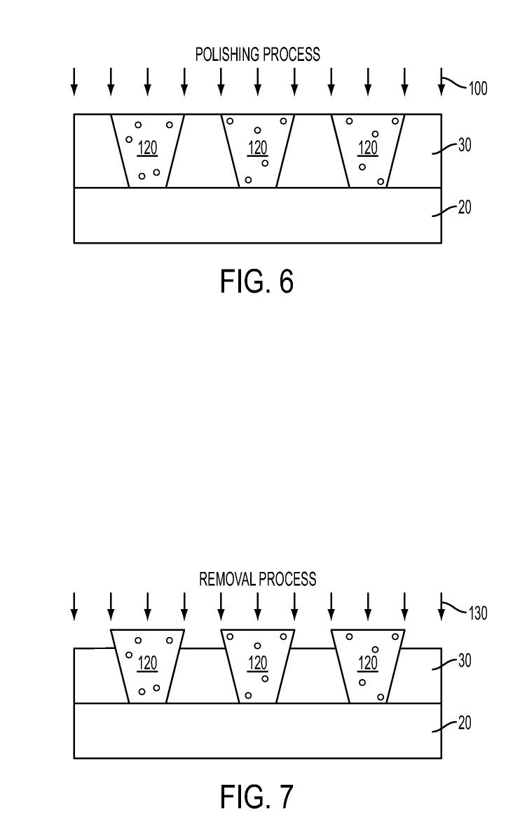

Referring now to FIG. 6, a polishing process 100 is performed on the dielectric material 90. In some embodiments, the polishing process 100 includes a chemical-mechanical-polishing (CMP) process. In some embodiments, the CMP process has a relatively high etching selectivity between the silicon oxide material of the dielectric material 90 and a material of the buffer layer 30. Generally, etching selectivity refers to the respective rates at which different materials are removed. A high etching selectivity results in a faster removal of one material in comparison with another material. The etching selectivity can be tuned by factors such as CMP slurry selection and downward pressure application (i.e., force applied to a CMP polishing head). The polishing process 100 substantially stops when a surface of the buffer layer 30 is reached. The portions of the dielectric material 90 remaining in the recesses 70A form shallow trench isolation (STI) structures 120. The front surface of the wafer 20 is substantially smooth and planarized after the completion of the polishing process 100

Referring now to FIG. 7, a removal process 130 is performed to remove a predetermined amount of a top surface of the planarized buffer layer 30 relative to a top surface of the STI structures 120. One purpose for removing an amount of the top surface of the buffer layer 30 is to later grow an insulator layer to reduce leakage in the semiconductor device 10. In some embodiments, the removal process 130 is performed by applying a chemical solution to the wafer 20. In some embodiments, the chemical solution includes hydrochloric acid (HCL) and hydrogen peroxide (H₂O₂). In some embodiments, the predetermined amount of the buffer layer removed ranges from about 1,000 Angstroms to about 3,000 Angstroms.

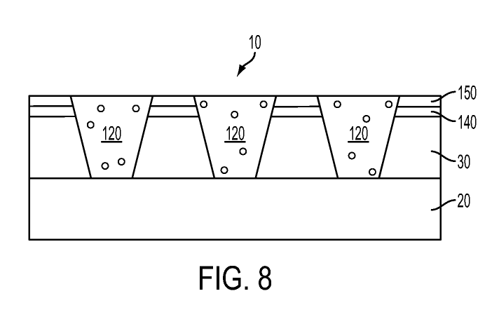

FIG. 8 illustrates the formation of III-V family layers on the wafer 20. A III-V family insulator layer 140 is formed over the buffer layer 30. The III-V family insulator layer 140 includes an element from a “III” family of the periodic table, and another element from a “V” family of the periodic table. For example, the III family elements may include: Boron, Aluminum, Gallium, etc, and the V family elements may include: Nitrogen, Phosphorous, Arsenic, etc. In some embodiments, the III-V family insulator layer 140 includes one of aluminum antimony (AlSb), aluminum antimony arsenic (AlSbAs), and aluminum gallium antimony (AlGaSb) material.

The III-V family insulator layer 140 may be formed by one or more epitaxial-growth processes known in the art, which may be performed at high temperatures. In some embodiments, the high temperatures range from about 350 degrees Celsius to about 1,000 degrees Celsius. In other embodiments, the III-V family insulator layer 140 may be formed by another suitable deposition process, such as for example chemical vapor deposition (CVD), low pressure chemical vapor deposition (LPCVD), atmospheric pressure chemical vapor deposition (APCVD), plasma enhanced chemical vapor deposition (PECVD), and reduced pressure chemical vapor deposition (RPCVD). In some embodiments, the III-V family insulator layer 140 has a thickness in a range from about 100 nanometers to about 300 nanometers.

Following the formation of the III-V family insulator layer 140 on the wafer 20, a III-V family channel layer 150 is formed over the insulator layer 140. When a transistor device (not shown) is turned on, the III-V family channel layer 150 allows a conductive channel to be formed below a gate device (not shown) and between the source/drain regions (not shown). An electrical current will flow in the III-V family channel layer 150. Like the III-V family insulator layer 140, the III-V family channel layer 150 includes an element from a “III” family of the periodic table, and another element from a “V” family of the periodic table. In some embodiments, the III-V family channel layer 150 includes one of indium gallium arsenic (InGaAs), indium arsenic (InAs), gallium antimony (GaSb), and indium gallium antimony (InGaSb) material.

The III-V family channel layer 150 may be formed by one or more epitaxial-growth processes known in the art, which may be performed at high temperatures. In an embodiment, the III-V family channel layer 150 has a thickness in a range from about 1 nanometer to about 50 nanometers.

The method for forming high mobility channels in III-V family channel devices according to the present disclosure offers advantages over traditional processes. It is understood, however, that other embodiments may offer different advantages, and that no particular advantage is required for all embodiments. One advantage is that the present disclosure eliminates or bypasses many processing steps that are required by traditional fabrication processes. These extra fabrication steps prolong fabrication time, waste fabrication resources, and increase fabrication cost. Another advantage offered by the embodiments disclosed herein is a reduced risk of causing wafer damage during processing by eliminating unnecessary handling of the wafer during fabrication.

Additional fabrication processes may be performed to complete the fabrication of the semiconductor device discussed herein. For example, gate devices, source/drain regions, interconnect structures, and passivation layers may be formed. Testing and packaging processes may also be performed. These processes are not shown or discussed herein for reasons of simplicity. By way of example, the methods disclosed herein may be used to form hetero-structure devices, light-emitting diode (LED) devices, radio-frequency (RF) devices, and high electron mobility transistor (HEMT) devices. The method and structure disclosed by the present disclosure may be applied to any III-V family device to achieve the various advantages discussed above.

In the preceding detailed description, specific exemplary embodiments have been described. It will, however, be apparent to a person of ordinary skill in the art that various modifications, structures, processes, and changes may be made thereto without departing from the broader spirit and scope of the present disclosure. The specification and drawings are, accordingly, to be regarded as illustrative and not restrictive. It is understood that embodiments of the present disclosure are capable of using various other combinations and environments and are capable of changes or modifications within the scope of the claims.

1. A method of fabricating a semiconductor device, comprising:
forming a buffer layer over a surface of a silicon substrate;
forming openings that extend into the buffer layer;
forming a shallow trench isolation (STI) structure in each of the openings;
removing a predetermined amount of a top surface of the buffer layer relative to a top surface of the STI structures;
forming an insulator layer over the top surface of the buffer layer; and
forming a channel layer over the insulator layer.

2. The method of claim 1, wherein the buffer layer includes a IV family material and a III-V family material.

3. The method of claim 2, wherein the IV family material includes at least one element in a IV family of the periodic table, and the III-V family material includes at least one element in a III family of the periodic table and at least one element in a V family of the periodic table.

4. The method of claim 2, wherein the IV family material includes one of silicon germanium (SiGe) and germanium (Ge), and the III-V family material includes one of gallium aresenic arsenic (GaAs), indium gallium arsenic (InGaAs), and indium arsenic (InAs).

5. The method of claim 1, wherein the buffer layer has a thickness ranging from about 1,000 Angstroms to about 10,000 Angstroms prior to the step of removing a predetermined amount of the top surface of the buffer layer.

6. The method of claim 1, wherein the forming the buffer layer over the surface of the silicon substrate is carried out using one of a metalorganic chemical vapor deposition (MOCVD), chemical vapor deposition (CVD), low pressure chemical vapor deposition (LPCVD), atmospheric pressure chemical vapor deposition (APCVD), plasma enhanced chemical vapor deposition (PECVD), or reduced pressure chemical vapor deposition (RPCVD) process.

7. The method of claim 1, further including: prior to forming the openings, forming a photoresist layer over the buffer layer, patterning the photoresist layer to form a patterned photoresist layer, wherein forming the openings is performed using the patterned photoresist layer.

8. The method of claim 1, wherein the predetermined amount of the buffer layer is from about 1,000 Angstroms to about 3,000 Angstroms.

9. The method of claim 1, wherein the insulator layer includes one of aluminum antimony (AlSb), aluminum antimony arsenic (AlSbAs), and aluminum gallium antimony (AlGaSb) material and the channel layer includes one of indium gallium arsenic (InGaAs), indium arsenic (InAs), gallium antimony (GaSb), and indium gallium antimony (InGaSb) material.

10. A method of fabricating a semiconductor device, comprising:
forming a buffer layer over a surface of a silicon substrate;
forming a patterned photoresist layer over the buffer layer;
etching a plurality of openings in the buffer layer, wherein the patterned photoresist layer serves as an etching mask during the etching;
filling the openings with a silicon oxide material to form a plurality of shallow trench isolation (STI) structures;
performing a polishing process on the silicon oxide material;
removing a predetermined amount of a top surface of the buffer layer relative to a top surface of the STI structures;
forming an insulator layer over the top surface of the buffer layer between adjacent STI structures of the plurality of STI structures; and
forming a channel layer over the insulator layer.

11. The method of claim 10, wherein the buffer layer includes a IV family material and a III-V family material, and wherein the IV family material includes at least one element in a IV family of the periodic table, and the III-V family material includes at least one element in a III family of the periodic table and at least one element in a V family of the periodic table.

12. The method of claim 10, wherein the buffer layer has a thickness of from about 1,000 Angstroms to about 10,000 Angstroms, prior to the step of removing a predetermined amount of the top surface of the buffer layer.

13. The method of claim 10, wherein the forming the buffer layer over the surface of the silicon substrate is carried out using one of a metalorganic chemical vapor deposition (MOCVD), chemical vapor deposition (CVD), low pressure chemical vapor deposition (LPCVD), atmospheric pressure chemical vapor deposition (APCVD), plasma enhanced chemical vapor deposition (PECVD), or reduced pressure chemical vapor deposition (RPCVD) process.

14. The method of claim 10, wherein the predetermined amount of the buffer layer is from about 1,000 Angstroms to about 3,000 Angstroms.

15. The method of claim 10, wherein the insulator layer includes one of aluminum antimony (AlSb), aluminum antimony arsenic (AlSbAs), and aluminum gallium antimony (AlGaSb) material and the channel layer includes one of indium gallium arsenic (InGaAs), indium arsenic (InAs), gallium antimony (GaSb), and indium gallium antimony (InGaSb) material.

16. A method of fabricating a semiconductor device, comprising:
providing a plurality of silicon wafers;
forming a buffer layer over a surface of each of the wafers;
forming a photoresist layer over the buffer layer;
patterning the photoresist layer to form a patterned photoresist layer;
etching a plurality of trenches in the buffer layer, wherein the patterned photoresist layer serves as an etching mask during the etching;
filling the trenches with a silicon oxide material to form a plurality of shallow trench isolation (STI) structures;
performing a chemical-mechanical-polishing (CMP) process on the silicon oxide material to planarize each of the wafers;
removing a predetermined amount of a top surface of the buffer layer relative to a top surface of the STI structures;
forming an insulator layer over the top surface of the buffer layer; and
forming a channel layer over the insulator layer.

17. The method of claim 16, wherein the buffer layer includes a IV family material and a III-V family material, wherein the IV family material includes at least one element in a IV family of the periodic table, and the III-V family material includes at least one element in a III family of the periodic table and at least one element in a V family of the periodic table.

18. The method of claim 16, wherein the buffer layer has a thickness of from about 1,000 Angstroms to about 10,000 Angstroms, prior to the step of removing a predetermined amount of the top surface of the buffer layer.

19. The method of claim 16, wherein the forming the buffer layer over the surface of the silicon substrate is carried out using one of a metalorganic chemical vapor deposition (MOCVD), chemical vapor deposition (CVD), low pressure chemical vapor deposition (LPCVD), atmospheric pressure chemical vapor deposition (APCVD), plasma enhanced chemical vapor deposition (PECVD), or reduced pressure chemical vapor deposition (RPCVD) process.

20. The method of claim 16, wherein the insulator layer includes one of aluminum antimony (AlSb), aluminum antimony arsenic (AlSbAs), and aluminum gallium antimony (AlGaSb) material and the channel layer includes one of indium gallium arsenic (InGaAs), indium arsenic (InAs), gallium antimony (GaSb), and indium gallium antimony (InGaSb) material.
